(19) United States
(12) Patent Application Publication
(10) Pub. No.: US 2024/0222267 A1
(43) Pub. Date: Jul. 4, 2024

(54) SEMICONDUCTOR DEVICES AND ELECTRONIC SYSTEMS INCLUDING THE SAME

(71) Applicant: SAMSUNG ELECTRONICS CO., LTD., Suwon-si (KR)

(72) Inventors: Byoungil LEE, Suwon-si (KR); Seungbeom KO, Suwon-si (KR); Jongyoon CHOI, Suwon-si (KR)

(21) Appl. No.: 18/396,813

(22) Filed: Dec. 27, 2023

(30) Foreign Application Priority Data
Dec. 28, 2022 (KR) 10-2022-0187759

(51) Int. Cl. H01L 23/522; G11C 16/04; H01L 23/528; H01L 25/065; H10B 41/10; H10B 41/27; H10B 41/35; H10B 43/10; H10B 43/27; H10B 43/35; H10B 80/00

(52) U.S. Cl. CPC H01L 23/5226; G11C 16/0483; H01L 23/5283; H01L 25/0652; H10B 41/10; H10B 41/27; H10B 41/35; H10B 43/10; H10B 43/27; H10B 43/35; H10B 80/00; H01L 2225/06506

(57) ABSTRACT

A semiconductor device comprising: a stack structure on a substrate including gate electrodes and insulating layers alternately stacked; a first through via extending through the stack structure; and a second through via spaced apart from the first through via, wherein the second through via extends through the stack structure, wherein the second through via is electrically connected to a first gate electrode that is farthest one among the gate electrodes from the substrate in the vertical direction, wherein a gate pad is on and contacts the first gate electrode, and the first through via includes: a vertical pattern; first and second protrusions that protrude from the vertical pattern, wherein the first protrusion overlaps a portion of the first gate electrode in the horizontal direction; and the second protrusion overlaps a second gate electrode in the horizontal direction, wherein the second gate electrode is spaced apart from the second through via.

### CROSS-REFERENCE TO RELATED APPLICATION

This application is based on and claims priority under 35 U.S.C. § 119 to Korean Patent Application No. 10-2022-0187759, filed on Dec. 28, 2022, in the Korean Intellectual Property Office, the disclosure of which is incorporated by reference herein in its entirety.

### BACKGROUND

The inventive concept relates to semiconductor devices and electronic systems including the same, and more particularly, to semiconductor devices including a non-volatile vertical memory device, and electronic systems including the same.

Semiconductor devices capable of storing high-capacity data have been demanded in electronic systems needing data storage, and accordingly, methods capable of increasing the data storage capacity of semiconductor devices have been studied. For example, as one of methods of increasing the data storage capacity of semiconductor devices, semiconductor devices, including vertical memory devices having three-dimensionally arranged memory cells instead of two-dimensionally arranged memory cells, have been proposed.

### SUMMARY

The inventive concept provides semiconductor devices having improved structural reliability.

According to an aspect of the inventive concept, there is provided a semiconductor device comprising: a substrate; a stack structure on an upper surface of the substrate, wherein the stack structure includes gate electrodes and insulating layers alternately stacked in a vertical direction that is perpendicular to the upper surface of the substrate and has a stepped structure in a cross-sectional view; a gate pad on the stack structure; a first through via that extends through the stack structure in the vertical direction; and a second through via that is spaced apart from the first through via in a horizontal direction that is parallel to the upper surface of the substrate, wherein the second through via extends through the stack structure in the vertical direction, wherein the second through via is electrically connected to a first gate electrode that is farthest one among the gate electrodes from the upper surface of the substrate in the vertical direction, wherein the gate pad is on the first gate electrode and is in contact with the first gate electrode, and wherein the first through via includes: a vertical pattern; a first protrusion that protrudes from the vertical pattern, wherein the first protrusion extends in the horizontal direction and overlaps at least a portion of the first gate electrode in the horizontal direction; and a second protrusion that protrudes from the vertical pattern, wherein the second protrusion extends in the horizontal direction and overlaps a second gate electrode in the horizontal direction, wherein the second gate electrode is between the first gate electrode and the upper surface of the substrate and spaced apart from the second through via.

According to another aspect of the inventive concept, there is provided a semiconductor device comprising: a substrate; a stack structure on an upper surface of the substrate, wherein the stack structure includes gate electrodes and insulating layers alternately stacked in a vertical direction that is perpendicular to the upper surface of the substrate and has a stepped structure in a cross-sectional view; a gate pad on the stack structure; a first through via that extends through the stack structure in the vertical direction, wherein the first through via includes a first insulating material; a second through via that is spaced apart from the first through via in a horizontal direction that is parallel to the upper surface of the substrate, wherein the second through via extends through the stack structure in the vertical direction and the second through via is electrically connected to a first gate electrode that is farthest one among the gate electrodes from the upper surface of the substrate in the vertical direction; and a vertical structure that is spaced apart from the first through via and the second through via, wherein the vertical structure extends through the stack structure in the vertical direction and includes a second insulating material, wherein the gate pad is on the first gate electrode and is in contact with the first gate electrode, and wherein the first through via includes: a vertical pattern; a first protrusion that protrudes from the vertical pattern, wherein the first protrusion extends in the horizontal direction and overlaps at least a portion of the first gate electrode in the horizontal direction; and a second protrusion that protrudes from the vertical pattern, wherein the second protrusion extends in the horizontal direction and overlaps a second gate electrode in the horizontal direction, wherein the second gate electrode is between the first gate electrode and the upper surface of the substrate and spaced apart from the second through via.

According to another aspect of the inventive concept, there is provided an electronic system comprising: a first substrate; a semiconductor device on the first substrate; and a controller electrically connected to the semiconductor device on the first substrate, wherein the semiconductor device includes: a second substrate; a stack structure disposed on an upper surface of the second substrate, wherein the stack structure includes gate electrodes and insulating layers alternately stacked in a vertical direction that is perpendicular to the upper surface of the second substrate and has a stepped structure in a cross-sectional view; a gate pad on the stack structure; a first through via that extends through the stack structure in the vertical direction; and a second through via that is spaced apart from the first through via in a horizontal direction that is parallel to the upper surface of the second substrate, wherein the second through via extends through the stack structure in the vertical direction, wherein the second through via is electrically connected to a first gate electrode that is farthest one among the gate electrodes from the upper surface of the second substrate in the vertical direction, wherein the gate pad is on the first gate electrode and is in contact with the first gate electrode, and wherein the first through via includes: a vertical pattern; a first protrusion that protrudes from the vertical pattern, wherein the first protrusion extends in the horizontal direction and overlaps at least a portion of the first gate electrode in the horizontal direction; and a second protrusion that protrudes from the vertical pattern, wherein the second protrusion extends in the horizontal direction and overlaps a second gate electrode in the horizontal direction, wherein the second gate electrode is between the first gate electrode and the upper surface of the second substrate and spaced apart from the second through via.

### BRIEF DESCRIPTION OF THE DRAWINGS

Embodiments will be more clearly understood from the following detailed description taken in conjunction with the accompanying drawings in which:

FIG. 1 is a block diagram of a semiconductor device according to some embodiments of the present inventive concept;

FIG. 2 is an equivalent circuit diagram of a memory cell array of a semiconductor device, according to some embodiments of the present inventive concept;

FIG. 3 is a perspective view illustrating a semiconductor device according to some embodiments of the present inventive concept;

FIG. 4 is a plan view illustrating a semiconductor device according to some embodiments of the present inventive concept;

FIG. 5 is a cross-sectional view taken along line A-A′ of FIG. 4;

FIG. 6 is an enlarged view of a portion EX of FIG. 5;

FIGS. 7A to 7P are cross-sectional views illustrating a method of manufacturing a semiconductor device, according to some embodiments of the present inventive concept;

FIG. 8 is a diagram schematically illustrating an electronic system including a semiconductor device, according to some embodiments of the present inventive concept;

FIG. 9 is a perspective view schematically illustrating an electronic system including a semiconductor device, according to some embodiments of the present inventive concept; and

FIG. 10 is a cross-sectional view schematically illustrating semiconductor packages according to some embodiments of the present inventive concept.

### DETAILED DESCRIPTION OF THE EMBODIMENTS

Hereinafter, embodiments will be described in detail with reference to the accompanying drawings. Like reference numerals in the drawings denote like elements unless otherwise specified, and thus their description may be omitted.

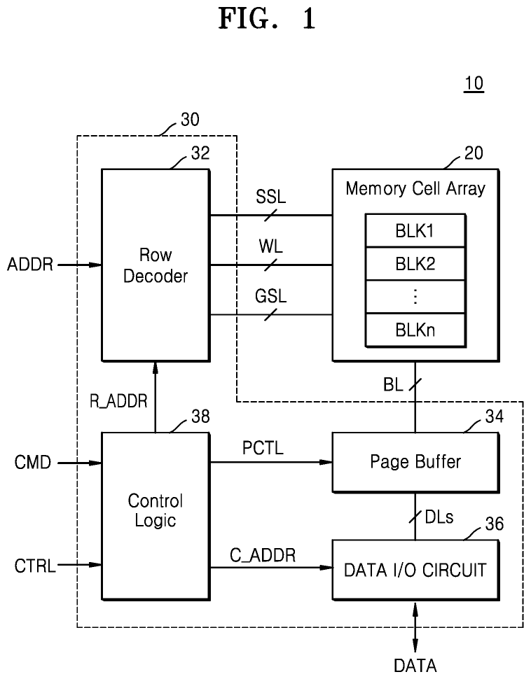

FIG. 1 is a block diagram of a semiconductor device 10 according to some embodiments of the present inventive concept.

Referring to FIG. 1, the semiconductor device 10 may include a memory cell array 20 and a peripheral circuit 30. The memory cell array 20 may include a plurality of memory cell blocks BLK1, BLK2, . . . , and BLKn. Each of the plurality of memory cell blocks BLK1, BLK2, . . . , and BLKn may include a plurality of memory cells. The plurality of memory cell blocks BLK1, BLK2, . . . , and BLKn may be electrically connected to the peripheral circuit 30 via a bit line BL, a word line WL, a string selection line SSL, and a ground selection line GSL.

The peripheral circuit 30 may include a row decoder 32, a page buffer 34, a data input/output (I/O) circuit 36, and a control logic 38. Although not illustrated in FIG. 1, the peripheral circuit 30 may further include, but is not limited to, an I/O interface, a column logic, voltage generator, a pre-decoder, a temperature sensor, a command decoder, an address decoder, an amplifier circuit, and the like.

The memory cell array 20 may be electrically connected to the page buffer 34 through the bit line BL, and may be electrically connected to the row decoder 32 through the word line WL, the string selection line SSL, and the ground selection line GSL. In the memory cell array 20, each of the plurality of memory cells included in each of the plurality of memory cell blocks BLK1, BLK2, . . . , and BLKn may be a flash memory cell, but is not limited thereto. The memory cell array 20 may include a three-dimensional memory cell array. The three-dimensional memory cell array may include a plurality of NAND strings, and each of the NAND strings may include a plurality of memory cells electrically connected to a plurality of word lines WL vertically stacked on a substrate.

The peripheral circuit 30 may receive an address ADDR, a command CMD, and a control signal CTRL from the outside of the semiconductor device 10, and may transmit and receive data DATA to and from a device outside the semiconductor device 10. As used hereinafter, the terms “external/outside device”, “external/outside signal”, or “outside” are intended to broadly refer to a device, circuit, block, module and/or signal that resides externally (i.e., outside of a functional or physical boundary) with respect to a given circuit, block, module, or device.

The row decoder 32 may select at least one of the plurality of memory cell blocks BLK1, BLK2, . . . , and BLKn in response to the address ADDR from the outside, and may select a word line WL, a string selection line SSL, and a ground selection line GSL of the selected memory cell block. The row decoder 32 may transmit a voltage for performing a memory operation to the word line WL of the selected memory cell block.

The page buffer 34 may be electrically connected to the memory cell array 20 through the bit line BL. The page buffer 34 may operate as a write driver during a program operation to apply, to the bit line BL, a voltage according to the data DATA to be stored in the memory cell array 20, and may operate as a sense amplifier during a read operation to sense the data DATA stored in the memory cell array 20. The page buffer 34 may operate according to a control signal PCTL provided from the control logic 38.

The data I/O circuit 36 may be electrically connected to the page buffer 34 through data lines DLs. The data I/O circuit 36 may receive the data DATA from a memory controller (not shown) during the program operation, and may provide program data to the page buffer 34 on the basis of a column address C_ADDR provided from the control logic 38. During the read operation, the data I/O circuit 36 may provide the memory controller with the read data stored in the page buffer 34, on the basis of the column address C_ADDR provided from the control logic 38.

The data I/O circuit 36 may transmit to the control logic 38 or the row decoder 32, an address or a command being input. The peripheral circuit 30 may further include, for example, an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and may provide a column address C_ADDR to the data I/O circuit 36. In response to the control signal CTRL, the control logic 38 may generate various types of internal control signals used within the semiconductor device 10. For example, the control logic 38 may adjust a voltage level provided to the word line WL and the bit line BL when performing a memory operation such as the program operation or an erase operation.

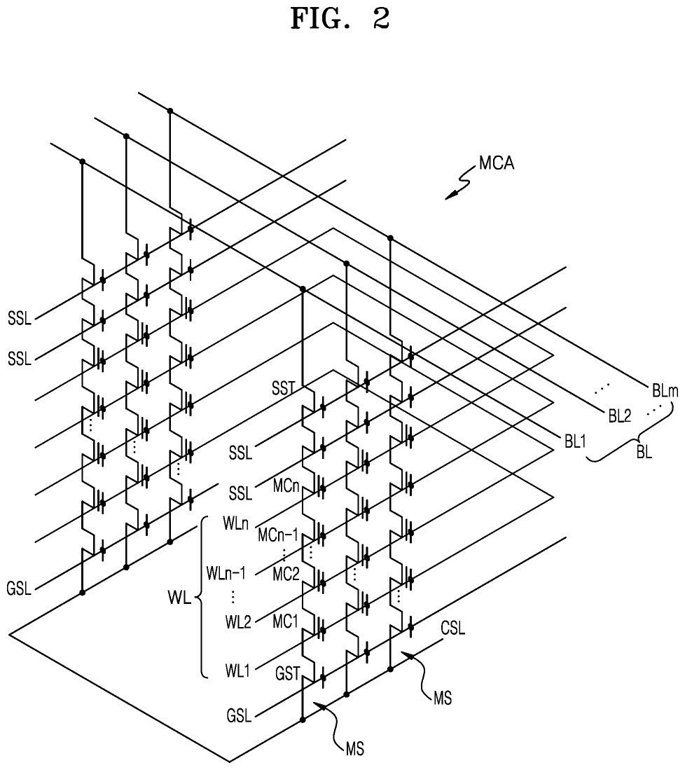

FIG. 2 is an equivalent circuit diagram of a memory cell array of the semiconductor device 10, according to some embodiments of the present inventive concept.

Referring to FIG. 2, a memory cell array MCA may include a plurality of memory cell strings MS. The memory cell array MCA may include a plurality of bit lines BL (BL1, BL2, . . . , and BLm), a plurality of word lines WL (WL1, WL2, . . . , WLn−1, and WLn), at least one string selection line SSL, at least one ground selection line GSL, and a common source line CSL. The plurality of memory cell strings MS may be formed between the plurality of bit lines BL (BL1, BL2, . . . , and BLm) and the common source line CSL. FIG. 2 illustrates an example in which each of the plurality of memory cell strings MS include two string selection lines SSL, but the inventive concept is not limited thereto. For example, each of the plurality of memory cell strings MS may also include one string selection line SSL.

Each of the plurality of memory cell strings MS may include a string selection transistor SST, a ground selection transistor GST, and a plurality of memory cell transistors MC1, MC2, . . . , MCn−1, and MCn. Drain regions of the string selection transistors SST may be electrically connected to the bit lines BL (BL1, BL2, . . . , and BLm), and source regions of the ground selection transistors GST may be electrically connected to the common source line CSL. The common source line CSL may be a region to which source regions of a plurality of ground selection transistors GST are commonly connected.

The string selection transistor SST may be electrically connected to the string selection line SSL, and the ground selection transistor GST may be electrically connected to the ground selection line GSL. The plurality of memory cell transistors MC1, MC2, . . . , MCn−1, and MCn may be respectively electrically connected to the plurality of word lines WL (WL1, WL2, . . . , WLn−1, and WLn).

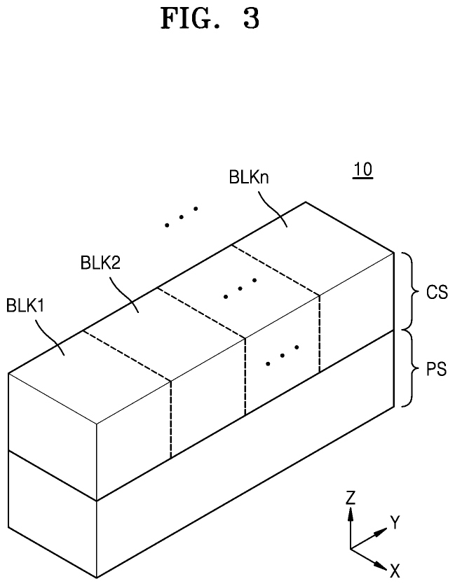

FIG. 3 is a perspective view illustrating a semiconductor device 10 according to some embodiments of the present inventive concept.

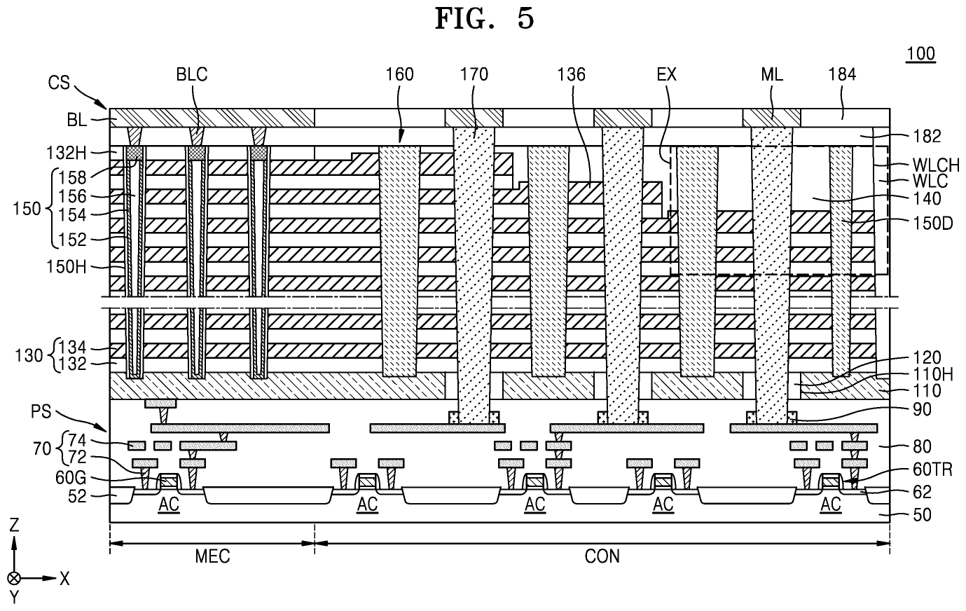

Referring to FIG. 3, the semiconductor device 10 may include a memory cell array structure CS and a peripheral circuit structure PS overlapping each other in a vertical direction. The vertical direction may be perpendicular to an upper surface of a substrate (e.g., substrate 50 in FIG. 5).

The memory cell array structure CS may include the memory cell array 20 described with reference to FIG. 1. The peripheral circuit structure PS may include the peripheral circuit 30 described with reference to FIG. 1.

The memory cell array structure CS may include a plurality of tiles. The plurality of tiles may respectively include a plurality of memory cell blocks BLK1, BLK2, . . . , BLKn. Each of the plurality of memory cell blocks BLK1, BLK2, . . . , and BLKn may include memory cells that are three-dimensionally arranged.

In some embodiments, two tiles may constitute one mat, but are not limited thereto. For example, the memory cell array 20 described with reference to FIG. 1 may include a plurality of mats.

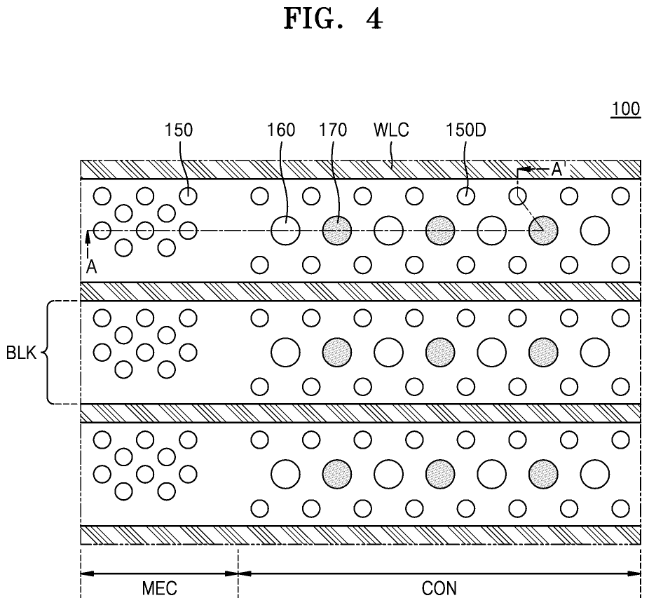

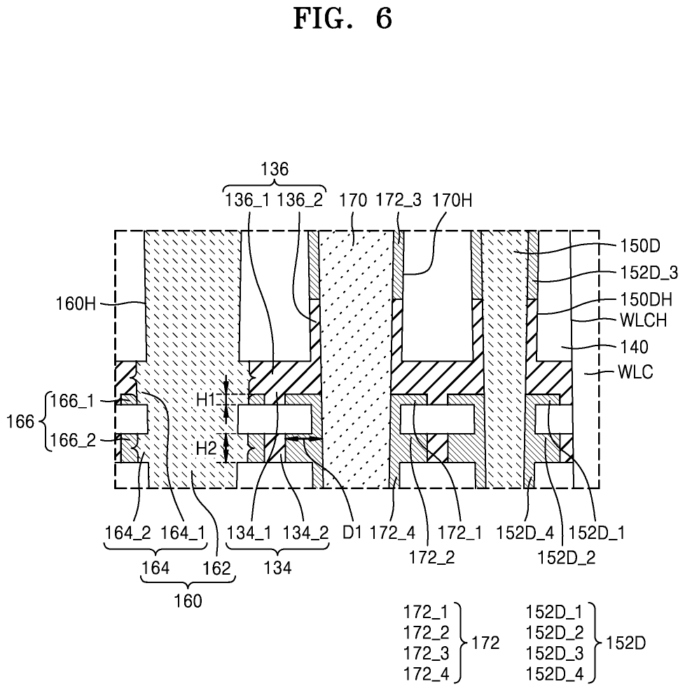

FIG. 4 is a plan view illustrating a semiconductor device 100 according to some embodiments of the present inventive concept. FIG. 5 is a cross-sectional view taken along line A-A′ of FIG. 4. FIG. 6 is an enlarged view of a portion EX of FIG. 5. A memory cell block BLK illustrated in FIG. 4 may include some of the plurality of memory cell blocks BLK1, BLK2, . . . , and BLKn illustrated in FIG. 3.

Referring to FIGS. 4 to 6, the semiconductor devices 100 may include a memory cell array structure CS and a peripheral circuit structure PS overlapping each other in a vertical direction (a Z direction).

The peripheral circuit structure PS may include a substrate 50, a peripheral circuit transistor 60TR disposed on the substrate 50, and a peripheral circuit wiring structure 70 disposed on the substrate 50.

The substrate 50 may include a semiconductor substrate, but is not limited thereto. For example, the substrate 50 may include Si, Ge, or SiGe, but is not limited thereto. The substrate 50 may include a memory cell region MEC and a connection region CON that are horizontally arranged. An active region AC may be defined by a device isolation layer 52 in the substrate 50, and a plurality of peripheral circuit transistors 60TR may be formed on the active region AC. Each of the plurality of peripheral circuit transistors 60TR may include a peripheral circuit gate 60G, and source/drain regions 62 arranged beside both sides of the peripheral circuit gate 60G on a portion of the substrate 50. The plurality of peripheral circuit transistors 60TR may include the peripheral circuit 30 described with reference to FIG. 1.

A plurality of peripheral circuit wiring structures 70 may include a plurality of peripheral circuit contacts 72 and a plurality of peripheral circuit wiring layers 74. At least some of the plurality of peripheral circuit wiring layers 74 may be configured to be electrically connected to the peripheral circuit transistor 60TR. The plurality of peripheral circuit contacts 72 may be configured to interconnect some selected from the plurality of peripheral circuit transistors 60TR and the plurality of peripheral circuit wiring layers 74. The plurality of peripheral circuit transistors 60TR and the plurality of peripheral circuit wiring structures 70 included in the peripheral circuit structure PS may be covered with an interlayer insulating layer 80 that may be disposed on the substrate 50. The interlayer insulating layer 80 may include a silicon oxide layer, a silicon nitride layer, an SiON layer, an SiOCN layer, or a combination thereof, but is not limited thereto.

A common source plate 110 may be disposed on the interlayer insulating layer 80. In some embodiments, the common source plate 110 may be a source region that supplies a current to vertical memory cells formed in the memory cell array structure CS. The common source plate 110 may be arranged on the memory cell region MEC and the connection region CON of the substrate 50.

In some embodiments, the common source plate 110 may include, for example, silicon (Si), germanium (Ge), silicon germanium (SiGe), gallium arsenide (GaAs), indium gallium arsenide (InGaAs), aluminum gallium arsenide (AlGaAs), and/or a combination thereof, but is not limited thereto. In some embodiments, the common source plate 110 may include semiconductor doped with n-type impurities. In addition, the common source plate 110 may have a crystal structure including, for example, a single crystal structure, an amorphous structure, and/or a polycrystalline structure. In some embodiments, the common source plate 110 may include polysilicon doped with n-type impurities.

The common source plate 110 may include a hole 110H arranged on the connection region CON of the substrate 50. An insulating plug 120 may fill the inside of the hole 110H of the common source plate 110. Here, an upper surface of the insulating plug 120 may be located at the same vertical level as an upper surface of the common source plate 110 relative to the upper surface of the substrate 50. For example, the upper surface of the insulating plug 120 may be coplanar with the upper surface of the common source plate 110.

A stack structure 130 may be disposed on the common source plate 110. The stack structure 130 may include a plurality of insulating layers 132 and a plurality of gate electrodes 134 that are alternately arranged in the vertical direction. The plurality of insulating layers 132 may include, for example, silicon oxide, silicon nitride, or silicon oxynitride, but is not limited thereto. The plurality of gate electrodes 134 may correspond to the ground selection line GSL, the word line WL (or the plurality of word lines WL), and at least one string selection line SSL included in the memory cell string MS of FIG. 2. For example, the uppermost one gate electrode 134 in FIG. 5 may be the ground selection line GSL, the lowermost two gate electrodes 134 in FIG. 5 may be the string selection lines SSL, and the remaining gate electrodes 134 may be the plurality of word lines WL. The plurality of gate electrodes 134 may include, for example, tungsten, nickel, cobalt, tantalum, tungsten nitride, titanium nitride, tantalum nitride, or a combination thereof, but is not limited thereto. The terms “lower” and “lowermost” may mean “closer” and “closest” to the substrate 50 in the vertical direction, respectively. The terms “higher/upper”, and “uppermost” may mean “farther” and “farthest” from the substrate 50 in the vertical direction, respectively.

A word line cut WLC filling a word line cut hole WLCH may be disposed on the common source plate 110. The word line cut WLC may include, for example, a silicon oxide layer, a silicon nitride layer, SiON, SiOCN, SiCN, or a combination thereof, but is not limited thereto.

In the memory cell region MEC, a plurality of channel structures 150 may extend in the vertical direction by passing through the plurality of insulating layers 132 and the plurality of gate electrodes 134, and may be arranged to be electrically connected to the common source plate 110. The plurality of channel structures 150 may be arranged to be spaced apart from each other at certain intervals in a first horizontal direction (e.g., an X direction), a second horizontal direction (e.g., a Y direction), and a third horizontal direction (e.g., a diagonal direction). The plurality of channel structures 150 may be arranged in a zigzag shape or a staggered shape to each other in a plan view. The first to third horizontal directions may be parallel with an upper surface of the substrate 50. Each of the first to third horizontal directions may be perpendicular to the vertical direction. The first to third horizontal directions may intersect with one another. In some embodiments, the first to third horizontal directions may be perpendicular to each other.

Each of the plurality of channel structures 150 may include a gate insulating layer 152, a channel layer 154, a buried insulating layer 156, and a conductive plug 158. The gate insulating layer 152, the channel layer 154, the buried insulating layer 156, and the conductive plug 158 may be disposed in a channel hole 150H that may extend in the vertical direction by passing through the plurality of insulating layers 132 and the plurality of gate electrodes 134. The gate insulating layer 152 and the channel layer 154 may be sequentially arranged on a sidewall of the channel hole 150H. For example, the gate insulating layer 152 may be conformally arranged on the sidewall of the channel hole 150H, and the channel layer 154 may be conformally arranged on the sidewall (e.g., on an inner sidewall of the gate insulating layer 152) and a lower surface of the channel hole 150H. The buried insulating layer 156 may be disposed in (e.g., fill) a remaining space of the channel hole 150H between inner sidewalls of the channel layer 154. For example, the channel layer 154 may extend around (e.g., surround) sidewalls and a lower surface of the buried insulating layer 156. The conductive plug 158 may be arranged to contact the channel layer 154 and/or the buried insulating layer 156, on an upper portion of the channel hole 150H. The conductive plug 158 may cover an entrance of the channel hole 150H. In some embodiments, the buried insulating layer 156 may be omitted, and here, the channel layer 154 may have a pillar shape without an empty space therein. The channel layer 154 may be disposed in (e.g., fill) a remaining space of the channel hole 150H between sidewalls of the gate insulating layer 152. The pillar shape herein may refer to a vertically extended shape (e.g., vertical pattern).

In some embodiments, the plurality of channel structures 150 may extend in the vertical direction by passing through at least a portion of the common source plate 110. Accordingly, a lower surface of the channel layer 154 of the channel structure 150 may be located at a lower vertical level than the upper surface of the common source plate 110. In some embodiments, the plurality of channel structures 150 may contact the upper surface of the common source plate 110. Accordingly, the lower surface of the channel layer 154 of the channel structure 150 may contact the upper surface of the common source plate 110.

In the connection region CON, the stack structure 130 may extend to have a shorter length in the first horizontal direction (the X direction) away from the common source plate 110. For example, the stack structure 130 may have shorter discrete lengths in the first horizontal direction as a vertical distance of the stack structure 130 from the common source plate 110 increases. The shorter discrete lengths herein may mean that the length of stack structure 130 does not gradually decrease but intermittently decrease along the increase of its vertical distance from the common source plate 110. For example, the stack structure 130 may have a stepped structure in a cross-sectional view. In the connection region CON, a gate pad 136 may be disposed on the plurality of gate electrodes 134 of the stack structure 130. For example, the gate pad 136 may be on a first gate electrode 134_1 located at an uppermost end from among the plurality of gate electrodes 134. The gate pad 136 and the first gate electrode 1341 may be connected to (e.g., in contact with) each other as a unitary structure. The unitary structure herein may refer to a single structure that includes the same material without visible boundary therein. The gate pad 136 may include a pad portion 136_1 and a pad protrusion 136_2. The pad portion 136_1 may be disposed on the first gate electrode 134_1, and may extend in the first horizontal direction (the X direction). The pad protrusion 1362 may be connected to the pad portion 1361, and may protrude from the pad portion 136_1 in the vertical direction (the Z direction). The gate pad 136 may extend around (e.g., surround) a portion of a dummy vertical structure 150D, a portion of a first through via 160, and a portion of a second through via 170.

In the connection region CON, a cover insulating layer 140 may be disposed on (e.g., cover) a plurality of insulating layers 132 and a plurality of gate pads 136. The cover insulating layer 140 may include, for example, a silicon oxide layer, but is not limited thereto.

A first upper insulating layer 182 may be disposed on the cover insulating layer 140 and an uppermost insulating layer 132H. The first upper insulating layer 182 may include, for example, silicon oxide, silicon nitride, silicon carbonitride, or a combination thereof, but is not limited thereto.

A plurality of dummy vertical structures 150D may be arranged in the connection region CON, and may extend in the vertical direction by passing through the cover insulating layer 140, the plurality of gate electrodes 134, and the plurality of insulating layers 132. The plurality of dummy vertical structures 150D may be arranged to be spaced apart from each other at certain intervals in the first horizontal direction (e.g., the X direction), the second horizontal direction (e.g., the Y direction), and the third horizontal direction (e.g., the diagonal direction). The plurality of dummy vertical structures 150D may be arranged in a zigzag shape or a staggered shape to each other in a plan view. The plurality of dummy vertical structures 150D may extend in the vertical direction by passing through at least a portion of the common source plate 110. Accordingly, lower surfaces of the plurality of dummy vertical structures 150D may be located at a lower vertical level than the upper surface of the common source plate 110.

The first gate electrode 134_1, the gate pad 136, and a dummy vertical insulating pattern 152D may extend around each of the plurality of dummy vertical structures 150D. For example, each of the plurality of dummy vertical structures 150D may be surrounded by the first gate electrode 134_1, the gate pad 136, and the dummy vertical insulating pattern 152D. For example, a region of the dummy vertical structure 150D located at a higher vertical level than an upper surface of the pad protrusion 1362 may be surrounded by a first sidewall dummy vertical insulating pattern 152D_3, and a region of the dummy vertical structure 150D located between the upper surface of the pad protrusion 136_2 and an upper surface of a first dummy vertical insulating pattern 152D_1 may be surrounded by the first gate electrode 134_1 and the gate pad 136, and a region of the dummy vertical structure 150D located at a lower vertical level than the upper surface of the first dummy vertical insulating pattern 152D_1 may be surrounded by the first dummy vertical insulating pattern 152D_1, a second dummy vertical insulating pattern 152D_2, and a second sidewall dummy vertical insulating pattern 152D_4.

The dummy vertical insulating pattern 152D may include the first dummy vertical insulating pattern 152D_1, the second dummy vertical insulating pattern 152D_2, the first sidewall dummy vertical insulating pattern 152D_3, and the second sidewall dummy vertical insulating pattern 152D_4. The first sidewall dummy vertical insulating pattern 152D_3 may be arranged on the sidewall of a dummy hole 150DH, and may be located, in the vertical direction, between the first upper insulating layer 182 and the pad protrusion 136_2. The first dummy vertical insulating pattern 152D_1 may be connected to the second sidewall dummy vertical insulating pattern 152D_4, may be disposed on the insulating layer 132 located underneath the first gate electrode 134_1, and may extend in the first horizontal direction. The second dummy vertical insulating pattern 152D_2 may be connected to the second sidewall dummy vertical insulating pattern 152D_4, and may be arranged underneath a lower surface of the insulating layer 132 located underneath the first gate electrode 1341, and may extend in the first horizontal direction. The second sidewall dummy vertical insulating pattern 152D_4 may be arranged on the sidewall of the dummy hole 150DH, and may extend from a lower surface of the first gate electrode 134_1 to the lower surface of the dummy hole 150DH. In some embodiments, the first dummy vertical insulating pattern 152D_1 and the second dummy vertical insulating pattern 152D_2 may have the same horizontal width D1 in the first horizontal direction (the X direction). The horizontal width D1 may be, for example, about 43 nm to about 47 nm, but is not limited thereto. In some embodiments, the first dummy vertical insulating pattern 152D_1, the second dummy vertical insulating pattern 152D_2, the first sidewall dummy vertical insulating pattern 152D_3, and the second sidewall dummy vertical insulating pattern 152D_4 may be integrally formed. For example, the first dummy vertical insulating pattern 152D_1, the second dummy vertical insulating pattern 152D_2, the first sidewall dummy vertical insulating pattern 152D_3, and the second sidewall dummy vertical insulating pattern 152D_4 may be formed by a same process. Accordingly, the first dummy vertical insulating pattern 152D_1, the second dummy vertical insulating pattern 152D_2, the first sidewall dummy vertical insulating pattern 152D_3, and the second sidewall dummy vertical insulating pattern 152D_4 may include the same material. In some embodiments, the first dummy vertical insulating pattern 152D_1, the second dummy vertical insulating pattern 152D_2, the first sidewall dummy vertical insulating pattern 152D_3, and the second sidewall dummy vertical insulating pattern 152D_4 may include silicon oxide. However, embodiments of the present inventive concept are not limited thereto.

A plurality of first through vias 160 may be arranged in the connection region CON, and may extend in the vertical direction by passing through the cover insulating layer 140, the plurality of gate electrodes 134, and the plurality of insulating layers 132. In some embodiments, the plurality of first through vias 160 may extend in the vertical direction by passing through at least a portion of the common source plate 110. Accordingly, lower surfaces of the plurality of first through vias 160 may be located at a lower vertical level than the upper surface of the common source plate 110.

The plurality of first through vias 160 may be arranged in a first through hole 160H. Each of the plurality of first through vias 160 may include a pillar 162 extending in the vertical direction inside the first through hole 160H, and a protrusion 164 connected to the pillar 162 and extending in the first horizontal direction. For example, the protrusion 164 may protrude from the pillar 162.

The protrusion 164 may include a first protrusion 164_1 located relatively higher and a second protrusion 164_2 located relatively lower in the vertical direction. The first protrusion 164_1 may be connected to the pillar 162, an upper region of the first protrusion 1641 may be surrounded by the first gate electrode 134_1 and the gate pad 136, and a lower region of the first protrusion 164_1 may be surrounded by a first-first through via insulating pattern 166_1. The second protrusion 164_2 may be connected to the pillar 162, and may be surrounded by a second-first through via insulating pattern 166_2. In some embodiments, the first protrusion 164_1 and the second protrusion 1642 may have sidewalls recessed inward toward the pillar 162. In some embodiments, the first protrusion 164_1 and the second protrusion 164_2 may have an annular shape on a plane perpendicular to the vertical direction. For example, the first protrusion 164_1 and the second protrusion 164_2 may protrude from the pillar 162.

In some embodiments, the first protrusion 1641 may extend in the first horizontal direction and may overlap at least a portion of the first gate electrode 134_1 in the first horizontal direction. The second protrusion 164_2 may extend in the first horizontal direction and may overlap the second gate electrode 134_2 in the first horizontal direction. For example, overlapping element A with element B in a horizontal direction herein may mean that element A has at least a portion at the same vertical distance as at least a portion of element B from an upper surface of a substrate (e.g., substrate 50).

In some embodiments, a portion of the first protrusion 1641 may overlap the first-first through via insulating pattern 166_1 in the first horizontal direction. The second protrusion 164_2 may overlap the second-first through via insulating pattern 166_2 in the first horizontal direction.

In some embodiments, the pillar 162 and the protrusion 164 may be integrally formed. For example, the pillar 162 and the protrusion 164 may be formed a same process. Accordingly, the pillar 162 and the protrusion 164 may include the same material. In some embodiments, the pillar 162 and the protrusion 164 may include an insulating material. For example, the pillar 162 and the protrusion 164 may include silicon oxide. However, embodiments of the present inventive concept are not limited thereto.

A first through via insulating pattern 166 may include the first-first through via insulating pattern 166_1 and the second-first through via insulating pattern 166_2. The first-first through via insulating pattern 166_1 may contact the first protrusion 164_1 on one side thereof, and may contact the first gate electrode 134_1 on the other side thereof. The second-first through via insulating pattern 166_2 may contact the second protrusion 164_2 on one side thereof, and may contact a second gate electrode 134_2 one the other side thereof. In some embodiments, the first-first through via insulating pattern 166_1 and the second-first through via insulating pattern 166_2 may be integrally formed. For example, the first-first through via insulating pattern 166_1 and the second-first through via insulating pattern 1662 may be formed by a same process. Accordingly, the first-first through via insulating pattern 166_1 and the second-first through via insulating pattern 166_2 may include the same material. In some embodiments, the first-first through via insulating pattern 166_1 and the second-first through via insulating pattern 166_2 may include silicon oxide. However, embodiments of the present inventive concept are not limited thereto. In some embodiments, the first-first through via insulating pattern 1661 may have a first thickness H1 in the vertical direction, and the second-first through via insulating pattern 166_2 may have, in the vertical direction, a second thickness H2 that is greater than the first thickness H1.

The second through via 170 may be arranged in the connection region CON, and may extend in the vertical direction by passing through the first upper insulating layer 182, the cover insulating layer 140, the plurality of gate electrodes 134, the plurality of insulating layers 132, the insulating plug 120, and a portion of the interlayer insulating layer 80. A lower portion of the second through via 170 may be connected to the peripheral circuit wiring layer 74 of the peripheral circuit wiring structure 70, and may be surrounded by a conductive landing via 90. The second through via 170 may be electrically connected to the peripheral circuit transistor 60TR via the conductive landing via 90 and the peripheral circuit wiring layer 74. The conductive landing via 90 may be disposed in (e.g., covered by) the interlayer insulating layer 80, and may be in contact with an upper surface of the peripheral circuit wiring layer 74. The conductive landing via 90 may include, for example, polysilicon doped with n-type impurities, but is not limited thereto.

In some embodiments, the second through via 170 may include a conductive material. For example, the second through via 170 may include tungsten, titanium, copper, aluminum, titanium nitride, tantalum nitride, tungsten nitride, or a combination thereof, but is not limited thereto.

The first gate electrode 134_1, the gate pad 136, and a second through via insulating pattern 172 may extend around the second through via 170. For example, the second through via 170 may be surrounded by the first gate electrode 1341, the gate pad 136, and the second through via insulating pattern 172, respectively. For example, a region of the second through via 170 located at a higher vertical level than an upper surface of the pad protrusion 136_2 may be surrounded by a first sidewall-second through via insulating pattern 172_3, a region of the second through via 170 located between the upper surface of the pad protrusion 136_2 and an upper surface of a first-second through via insulating pattern 172_1 may be surrounded by the first gate electrode 134_1 and the gate pad 136, and a region of the second through via 170 located at a lower vertical level than the upper surface of the first-second through via insulating pattern 172_1 may be surrounded by the first-second through via insulating pattern 172_1, a second-second through via insulating pattern 172_2, and a second sidewall-second through via insulating pattern 172_4.

The second through via insulating pattern 172 may include the first-second through via insulating pattern 172_1, the second-second through via insulating pattern 172_2, a first sidewall-second through via insulating pattern 172_3, and the second sidewall-second through via insulating pattern 172_4. The first sidewall-second through via insulating pattern 172_3 may be arranged on a sidewall of the second through hole 170H, and may be located, in the vertical direction, between the first upper insulating layer 182 and the pad protrusion 136_2. The first-second through via insulating pattern 172_1 may be connected to the second sidewall-second through via insulating pattern 172_4, may disposed on the insulating layer 132 located underneath the first gate electrode 134_1, and may extend in the first horizontal direction. The second-second through via insulating pattern 172_2 may be connected to the second sidewall-second through via insulating patter 172_4, may be arranged underneath the lower surface of the insulating layer 132 located underneath the first gate electrode 134_1, and may extend in the first horizontal direction. The second sidewall-second through via insulating pattern 172_4 may be arranged on the sidewall of the second through hole 170H, and may extend from the lower surface of the first gate electrode 134_1 to a lower surface of the second through hole 170H. In some embodiments, the first-second through via insulating pattern 172_1 and the second-second through via insulating pattern 172_2 may have the same horizontal width in the first horizontal direction (the X direction). The horizontal width may be, for example, about 43 nm to about 47 nm, but is not limited thereto. In some embodiments, the first-second through via insulating pattern 172_1 may overlap, in the first horizontal direction, the first dummy vertical insulating pattern 152D_1 surrounding the dummy vertical structure 150D, and the second-second through via insulating pattern 172_2 may overlap, in the first horizontal direction, the second dummy vertical insulating pattern 152D_2 surrounding the dummy vertical structure 150D. For example, upper surface and/or lower surface of the first-second through via insulating pattern 172_1 may be located at the same vertical level as upper surface and/or lower surface of the first dummy vertical insulating pattern 152D_1, and upper surface and/or lower surface of the second-second through via insulating pattern 172_2 may be located at the same vertical level as upper surface and/or lower surface of the second dummy vertical insulating pattern 152D_2. In some embodiments, the first-second through via insulating pattern 172_1, the second-second through via insulating pattern 172_2, the first sidewall-second through via insulating pattern 172_3, and the second sidewall-second through via insulating pattern 172_4 may be integrally formed. For example, the first-second through via insulating pattern 172_1, the second-second through via insulating pattern 172_2, the first sidewall-second through via insulating pattern 172_3, and the second sidewall-second through via insulating pattern 172_4 may be concurrently formed by same processes such as a same deposition process and/or a same etching process, but not limited thereto. Accordingly, the first-second through via insulating pattern 172_1, the second-second through via insulating pattern 172_2, the first sidewall-second through via insulating pattern 172_3, and the second sidewall-second through via insulating pattern 172_4 may include the same material. In some embodiments, the first-second through via insulating pattern 172_1, the second-second through via insulating pattern 172_2, the first sidewall-second through via insulating pattern 172_3, and the second sidewall-second through via insulating pattern 172_4 may include silicon oxide. However, embodiments of the present inventive concept are not limited thereto.

On a plane (i.e., an X-Y plane) perpendicular to the vertical direction (the Z direction), the first through vias 160 and the second through vias 170 may be alternately arranged in one direction. For example, the first through vias 160 and the second through vias 170 may be alternately arranged in the first horizontal direction (the X direction).

In the memory cell region MEC, each of a plurality of bit line contacts BLC may contact the conductive plug 158 of the channel structure 150 by passing through the first upper insulating layer 182. The plurality of bit line contacts BLC may be insulated from each other by the first upper insulating layer 182.

A second upper insulating layer 184 may be disposed on the first upper insulating layer 182. The second upper insulating layer 184 may include, for example, silicon nitride, silicon oxide, silicon carbonitride, or a combination thereof, but is not limited thereto.

In the memory cell region MEC, the bit line BL may be disposed on the bit line contact BLC by passing through the second upper insulating layer 184.

In the connection region CON, a plurality of wiring layers ML may be disposed on the second through via 170 by passing through the second upper insulating layer 184. The plurality of wiring layers ML may be insulated from each other by the second upper insulating layer 184.

The semiconductor device 100 according to some embodiments may include the first through via 160, and the second through via 170 connected to the peripheral circuit wiring layer 74, and the second through via 170 and the gate electrode 134 may be formed by using the first through via 160. Accordingly, in a process of forming the first gate electrode 134_1 electrically connected to (e.g., contacting) the second through via 170 and the second gate electrode 134_2 that does not contact the second through via 170, a separation distance between the first gate electrode 134_1 and the second gate electrode 134_2 may be secured, and thus, the structural reliability of the semiconductor device 100 may be improved.

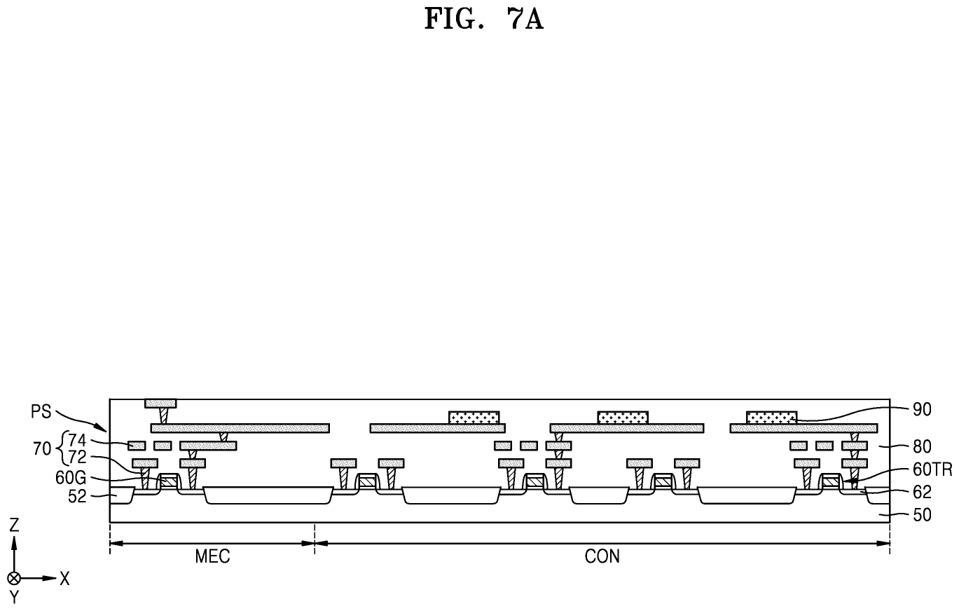

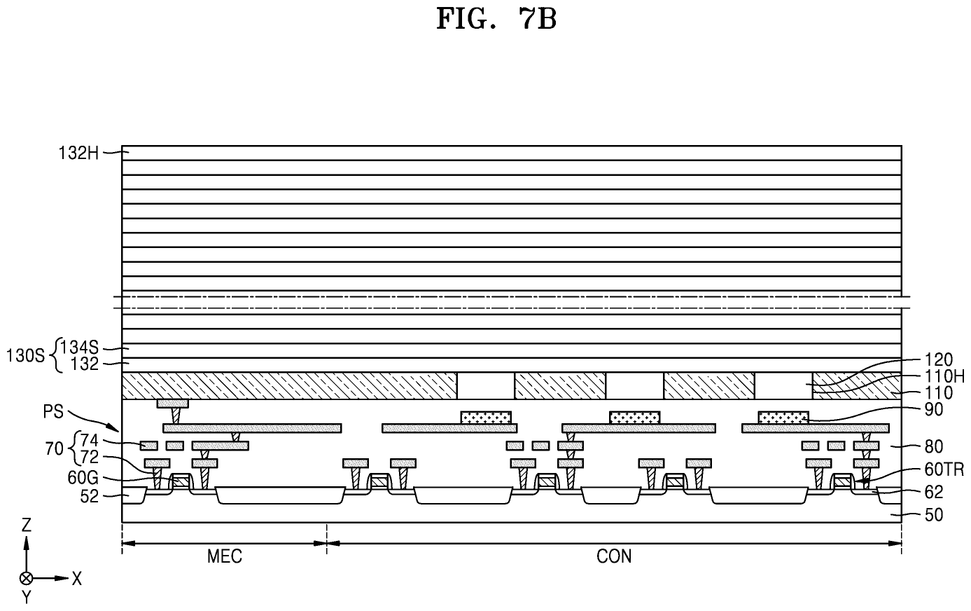

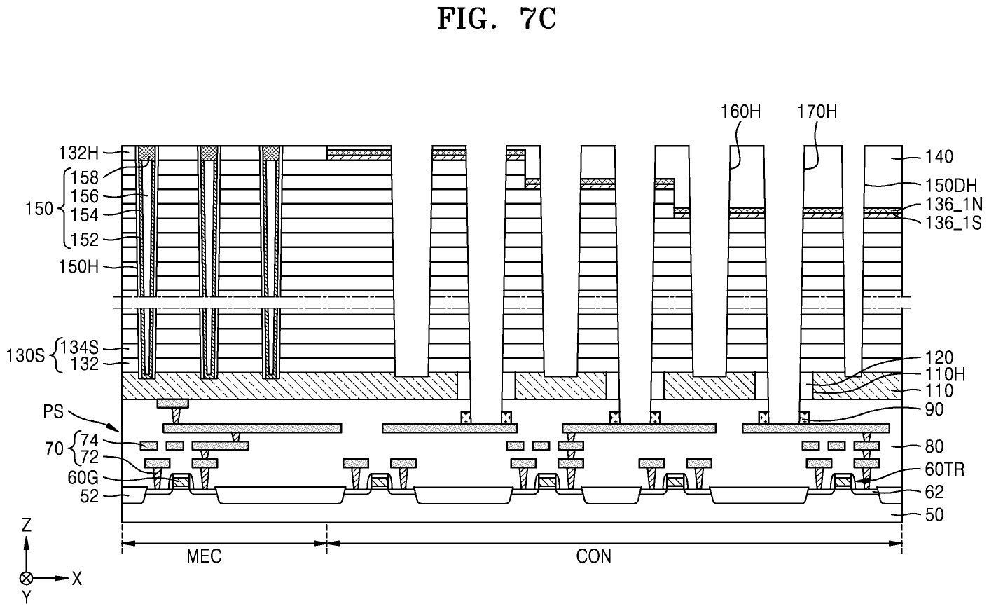

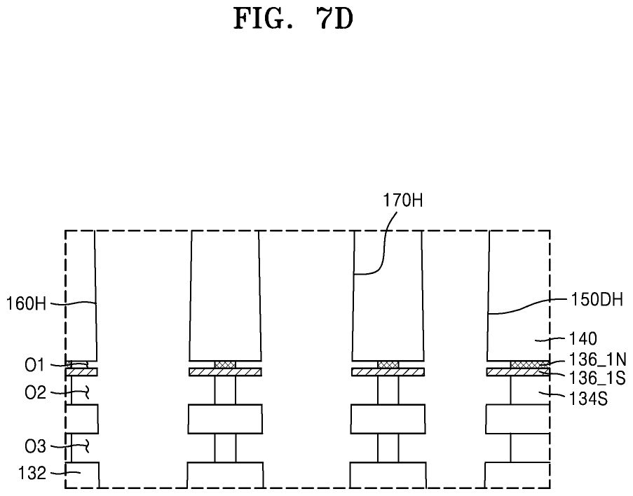

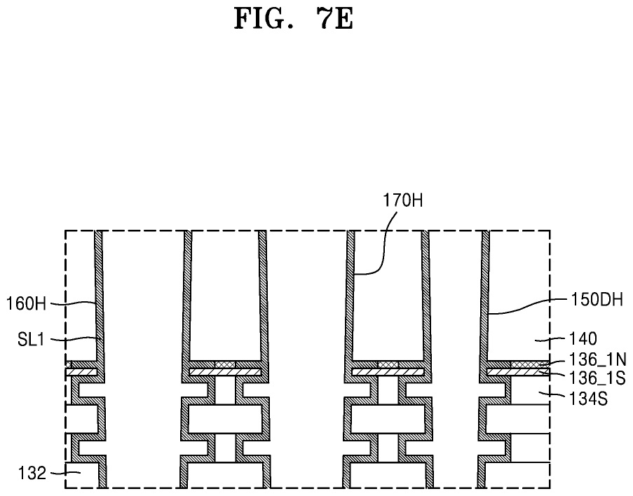

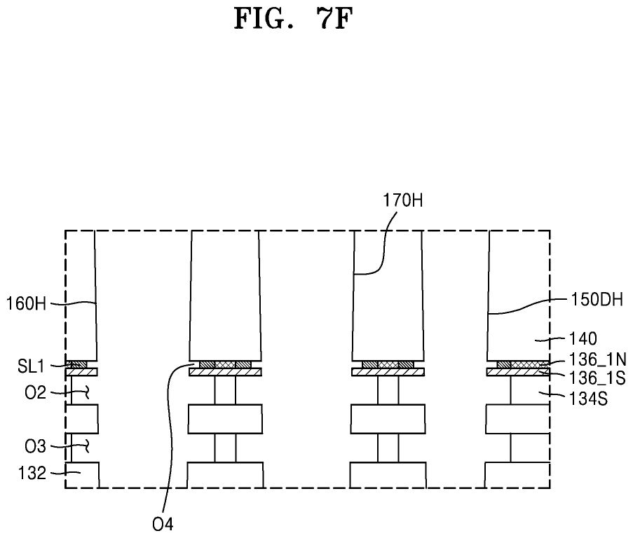

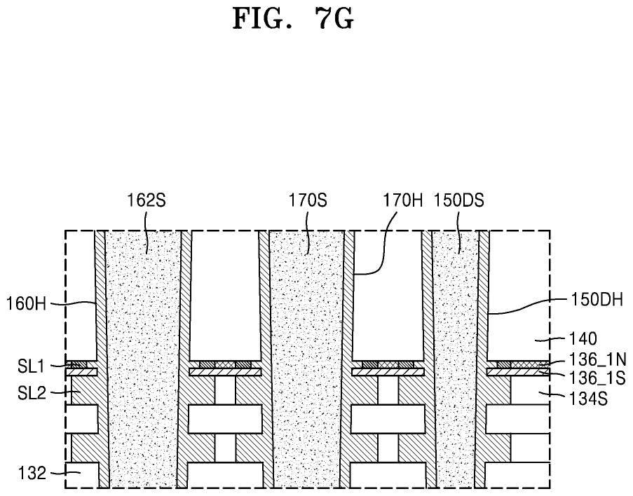

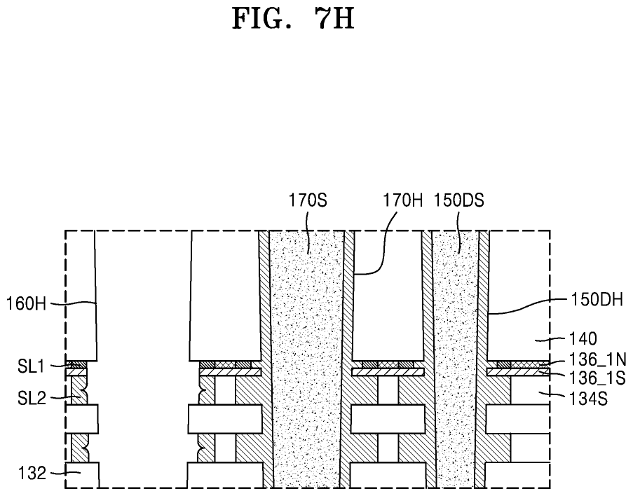

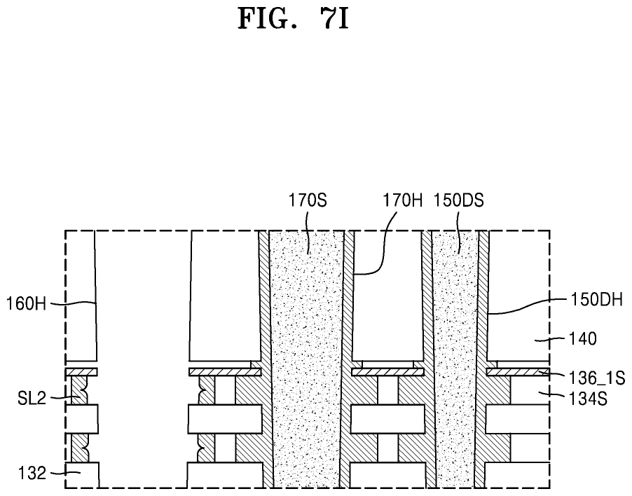

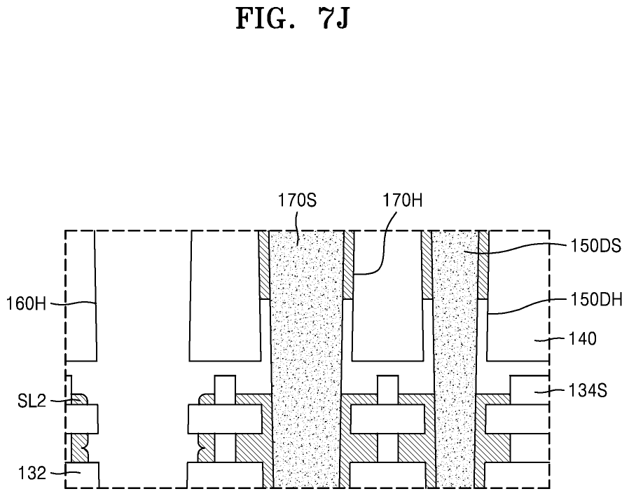

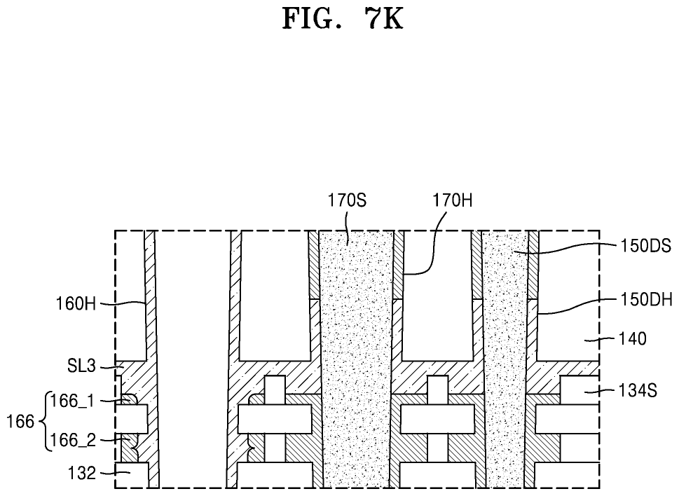

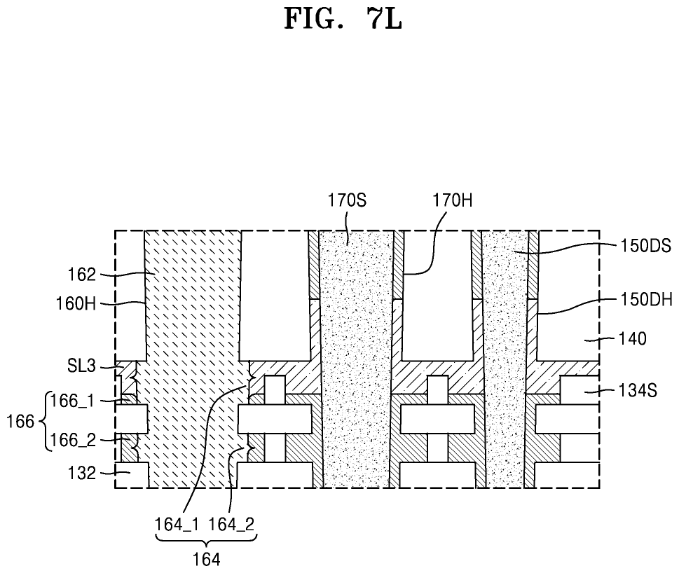

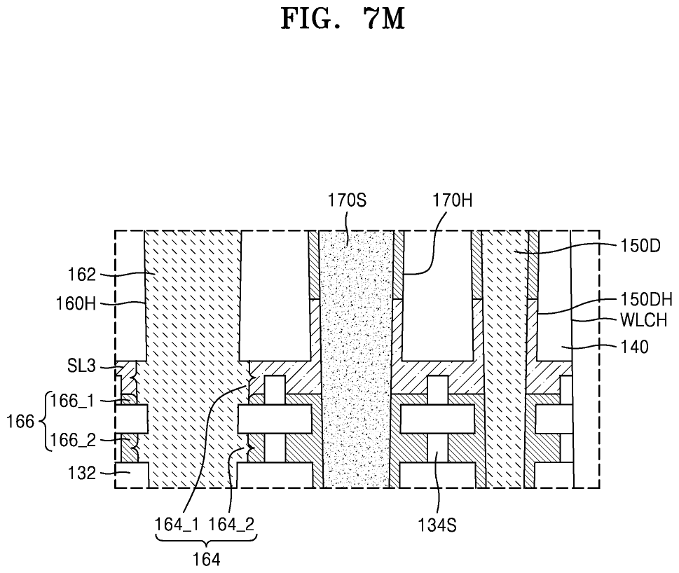

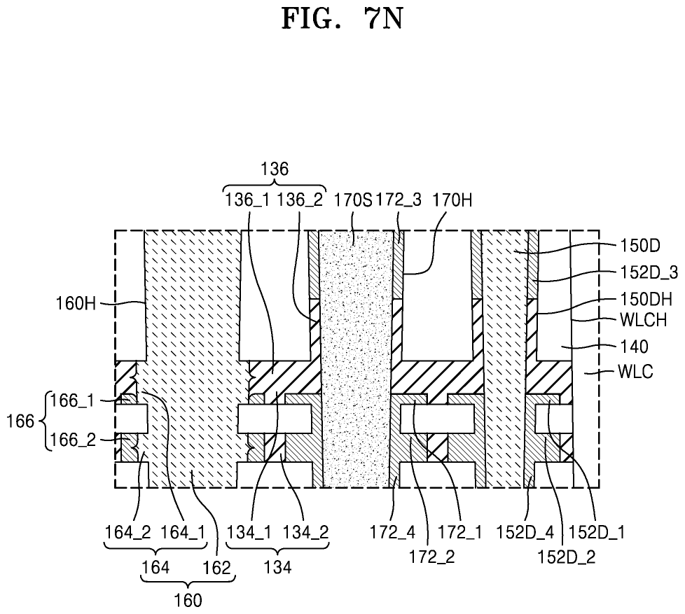

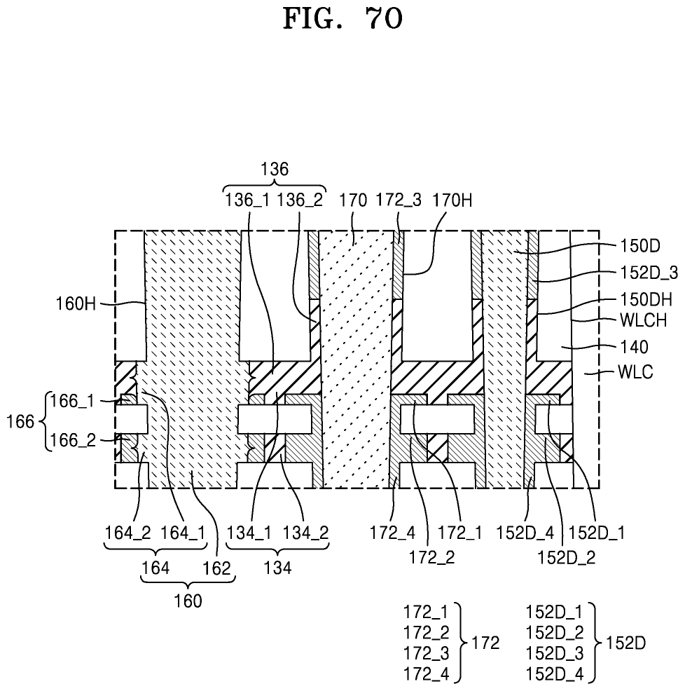

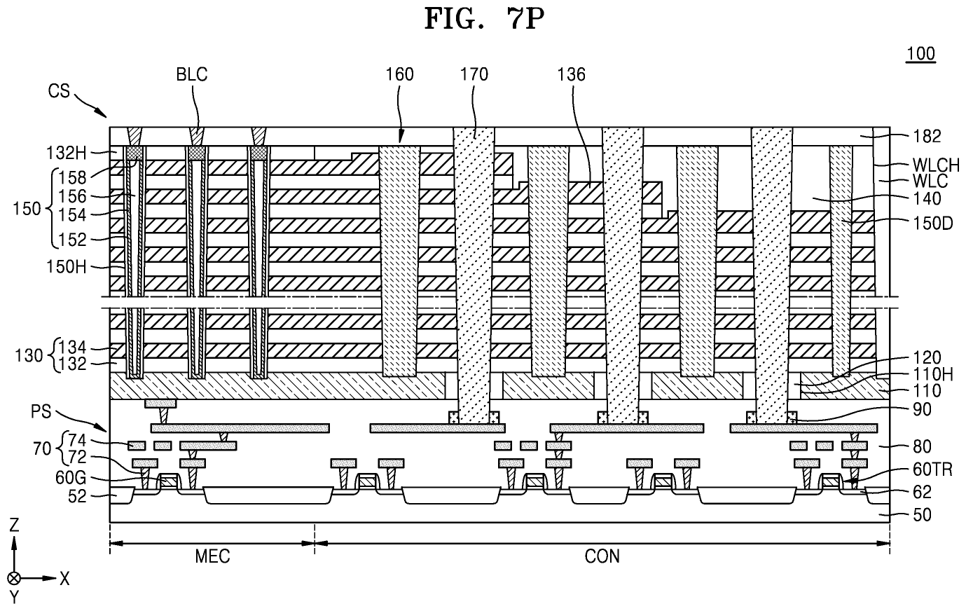

FIGS. 7A to 7P are cross-sectional views illustrating a method of manufacturing a semiconductor device, according to some embodiments. For example, FIGS. 7A to 7C and 7P are cross-sectional views illustrating a region corresponding to FIG. 5, and FIGS. 7D to 7O are cross-sectional views illustrating a region corresponding to FIG. 6.

Referring to FIG. 7A, a peripheral circuit structure PS may be formed on a substrate 50. For example, a plurality of peripheral circuit transistors 60TR may be formed on the substrate 50. A peripheral circuit wiring structure 70 which are electrically connected to the peripheral circuit transistor 60TR are formed on the substrate 50. An interlayer insulating layer 80 may be formed on the peripheral circuit transistor 60TR, the peripheral circuit wiring structure 70, and the substrate 50.

In a connection region CON, a conductive landing via 90 may be further formed on an uppermost peripheral circuit wiring layer 74. The conductive landing via 90 may be formed by using, for example, polysilicon doped with n-type impurities, but is not limited thereto. The interlayer insulating layer 80 may be on the conductive landing via 90. For example, the conductive landing via 90 may be covered by the interlayer insulating layer 80.

Referring to FIG. 7B, in the resultant structure of FIG. 7A, a common source plate 110 may be formed on the interlayer insulating layer 80. The common source plate 110 may be formed by using, for example, semiconductor doped with n-type impurities, but is not limited thereto. Subsequently, a mask pattern (not shown) may be formed on the common source plate 110, and a hole 110H may be formed by using the mask pattern as an etching mask. The hole 110H may be formed to overlap at least a portion of the connection region CON in the vertical direction. Subsequently, an insulating plug 120 filling the hole 110H may be formed. Subsequently, a plurality of insulating layers 132 and a plurality of sacrificial layers 134S may be alternately formed on the common source plate 110. In some embodiments, the plurality of insulating layers 132 may include an insulating material, such as silicon oxide or silicon oxynitride, but is not limited thereto, and the plurality of sacrificial layers 134S may include silicon nitride, silicon oxynitride, impurity-doped polysilicon, or the like, but is not limited thereto.

Referring to FIG. 7C, in the resultant structure of FIG. 7B, after forming a mask pattern (not shown), a preliminary stack structure 130S having a stepped structure in a cross-sectional view may be formed in the connection region CON by repeatedly performing an etching process using the mask pattern as an etching mask. For example, the preliminary stack structure 130S may have shorter discrete lengths in the first horizontal direction as a vertical distance of the preliminary stack structure 130S from the common source plate 110 increases. Subsequently, a pad isolation layer 136_1S and a pad sacrificial layer 136_1N may be sequentially formed on the sacrificial layer 134S located at the uppermost end from among the plurality of sacrificial layers 134S. In some embodiments, the pad isolation layer 136_1S may include silicon oxide, but is not limited thereto, and the pad sacrificial layer 136_1N may include silicon nitride, but is not limited thereto. Subsequently, a cover insulating layer 140 may be formed on (e.g., cover) the pad sacrificial layer 136_1N. Subsequently, after forming a mask pattern (not shown), by using the mask pattern as an etching mask, a dummy hole 150DH and a first through hole 160H, which pass through the preliminary stack structure 130S, the cover insulating layer 140, the pad isolation layer 136_9S, and the pad sacrificial layer 136_1N, may be formed in the connection region CON, and a channel hole 150H, which passes through the preliminary stack structure 130S, may be formed in a memory cell region MEC. Subsequently, a channel structure 150 may be formed inside the channel hole 150H. Subsequently, a second through hole 170H, which passes through the preliminary stack structure 130S, the cover insulating layer 140, the pad isolation layer 136_9S, the pad sacrificial layer 136_1N, the insulating plug 120, a portion of the interlayer insulating layer 80, and the conductive landing via 90, may be formed in the connection region CON.

Referring to FIG. 7D, in the resultant structure of FIG. 7C, first, second, and third openings O1, O2, and O3 may be formed by removing a portion of the pad sacrificial layer 136_1N and portions of the plurality of sacrificial layers 134S by performing a first pullback process. In some embodiments, the first pullback process may be a process using an etching recipe in which an etching rate with respect to the pad sacrificial layer 136_1N and the plurality of sacrificial layers 134S is relatively high and an etching rate with respect to the pad isolation layer 136_1S and the plurality of insulating layers 132 is relatively low. The first opening may be adjacent the pad sacrificial layer 136_1N (e.g., the recessed pad sacrificial layer). The second and third openings may be adjacent the sacrificial layers 134S (e.g., the recessed sacrificial layers).

Referring to FIG. 7E, in the resultant structure of FIG. 7D, a first sacrificial layer SL1 may be formed on (e.g., cover) a sidewall of the dummy hole 150DH, a sidewall of the first through hole 160H, a sidewall of the second through hole 170H, and in the first, second, and third openings O1, O2, and O3. The first sacrificial layer SL1 may include, for example, silicon nitride, but is not limited thereto. The first sacrificial layer SL1 may entirely fill the first opening O1, and may not entirely fill the second, and third openings O2, and O3.

Referring to FIG. 7F, in the resultant structure of FIG. 7E, the first sacrificial layer SL1 may be partially removed by performing a second pullback process. The remained first sacrificial layer SL1 after the second pullback process may be adjacent the cover insulating layer 140, the pad sacrificial layer 136_1N, and the pad isolation layer 136_1S. Here, the first sacrificial layer SL1 may remain only in a partial region of the first opening O1 of FIG. 7D surrounded by the cover insulating layer 140, the pad sacrificial layer 136_1N, and the pad isolation layer 136_1S, and may be fully removed from the other regions such as the second and third openings O2 and O3. In some embodiments, a fourth opening O4 may be formed in the region of the first opening O1 from which the first sacrificial layer SL1 is removed. For example, the fourth opening O4 may be a remaining region of the first opening O1 that is not filled with the remained first sacrificial layer SL1.

Referring to FIG. 7G, in the resultant structure of FIG. 7F, a second sacrificial layer SL2 may be disposed on (e.g., cover) the sidewall of the dummy hole 150DH, the sidewall of the first through hole 160H, the sidewall of the second through hole 170H, and in the second, third, and fourth openings O2, O3, and O4. The second sacrificial layer SL2 may entirely fill the second, third, and fourth openings O2, O3, and O4. In some embodiments, the second sacrificial layer SL2 may include silicon oxide, but is not limited thereto. Subsequently, the dummy hole 150DH, the first through hole 160H, and the second through hole 170H may be filled with dummy hole sacrificial layer 150DS, first through hole sacrificial layer 162S, and second through hole sacrificial layer 170S, respectively. In some embodiments, the dummy hole sacrificial layer 150DS, the first through hole sacrificial layer 162S, and the second through hole sacrificial layer 170S may include polysilicon that is undoped with impurities, but are not limited thereto.

Referring to FIGS. 7H and 7I, in the resultant structure of FIG. 7G, the first through hole sacrificial layer 162S, which fills the first through hole 160H, may be removed. Subsequently, the first sacrificial layer SL1, which is surrounded by the cover insulating layer 140, the pad sacrificial layer 136_9N, and the pad isolation layer 136_9S, may be exposed by removing a portion of the second sacrificial layer SL2 on (e.g., covering) the first through hole 160H. Subsequently, the exposed first sacrificial layer SL1 and the pad sacrificial layer 136_9N may be removed.

Referring to FIG. 7J, in the resultant structure of FIG. 7I, the pad isolation layer 136_1S and a portion of the second sacrificial layer SL2 may be removed. In some embodiments, the pad isolation layer 136_1S and the portion of the second sacrificial layer SL2 may be removed by performing an etching process that uses HF as an etchant. When the pad isolation layer 136_9S and the portion of the second sacrificial layer SL2 are removed, an upper surface and at least portions of both sidewalls of the sacrificial layer 134S located at the uppermost end from among the plurality of sacrificial layers 134S may be exposed. The remained second sacrificial layer SL2 may include the first through via insulating pattern 166, the second through via insulating pattern 172, and the dummy vertical insulating pattern 152D.

Referring to FIG. 7K, in the resultant structure of FIG. 7J, a third sacrificial layer SL3 may be disposed on (e.g., fill) a space from which the first sacrificial layer SL1 of FIG. 7H, the pad sacrificial layer 136_1N of FIG. 7H, the pad isolation layer 136_1S of FIG. 7I, and the portion of the second sacrificial layer SL2 are removed. The third sacrificial layer SL3 may include, for example, silicon nitride, but is not limited thereto.

Referring to FIG. 7L, in the resultant structure of FIG. 7K, a portion of the third sacrificial layer SL3 on (e.g., covering) a sidewall of the first through hole 160H may be removed. Subsequently, a first through via 160 of FIG. 6 including a pillar 162 and a protrusion 164 may be formed by filling oxide in the first through hole 160H and the portion, from which the third sacrificial layer SL3 is removed.

Referring to FIG. 7M, in the resultant structure of FIG. 7L, the dummy hole sacrificial layer 150DS filling the dummy hole 150DH may be removed, and oxide may fill the dummy hole 150DH. Accordingly, a dummy vertical structure 150D may be formed. Subsequently, an extension portion of a second through hole 170H, which passes through a word line cut hole WLCH and the first upper insulating layer 182 of FIG. 5, may be formed by forming the first upper insulating layer 182 on the cover insulating layer 140, forming a mask pattern (not shown), and using the mask pattern as an etching mask.

Referring to FIG. 7N, in the resultant structure of FIG. 7M, a gate electrode 134 and a gate pad 136 may be formed by removing the plurality of sacrificial layers 134S of FIG. 7M exposed by the word line cut hole WLCH and filling a conductive material in a space from which the plurality of sacrificial layers 134S are removed. Subsequently, a word line cut WLC may be formed by filling the word line cut hole WLCH with an insulating material.

Referring to FIG. 7O, in the resultant structure of FIG. 7N, a second through via 170 may be formed by removing the second through hole sacrificial layer 170S filling the second through hole 170H and filling a conductive material in the second through hole 170H from which the second through hole sacrificial layer 170S is removed.

Referring to FIG. 7P, in the resultant structure of FIG. 7O, a bit line contact BLC, which passes through the first upper insulating layer 182 in the memory cell region MEC and overlaps each of the plurality of channel structures 150 in a vertical direction, may be formed. The bit line contact BLC may be electrically connected (e.g., in contact with) each of the plurality of channel structures 150 (e.g., conductive plug 158).

Subsequently, in the resultant structure of FIG. 7P, the second upper insulating layer 184 of FIG. 5 may be formed on the first upper insulating layer 182. Subsequently, the bit line BL of FIG. 5, which passes through the second upper insulating layer 184 and is electrically connected to the bit line contact BLC of FIG. 7P, may be formed in the memory cell region MEC, and a wiring layer ML of FIG. 5, which passes through the second upper insulating layer 184 and is electrically connected to the second through via 170 of FIG. 7P, may be formed in the connection region CON of FIG. 7P, and thus, the semiconductor device 100 described with reference to FIGS. 5 and 6 may be manufactured.

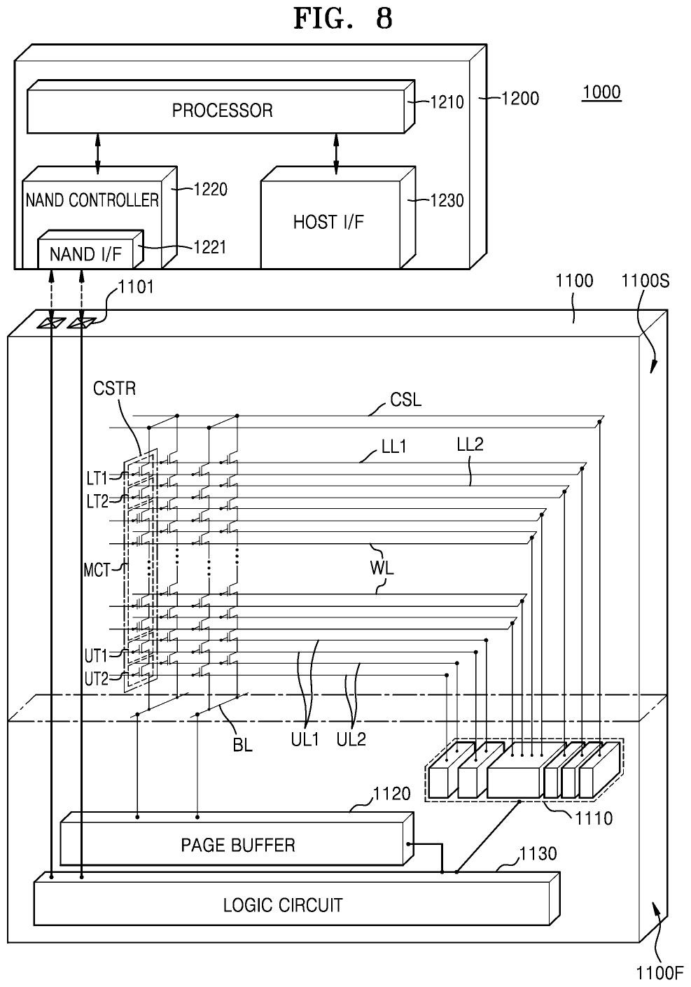

FIG. 8 is a diagram schematically illustrating an electronic system 1000 including a semiconductor device, according to some embodiments of the present inventive concept.

Referring to FIG. 8, the electronic system 1000 according to some embodiments may include a semiconductor device 1100, and a controller 1200 electrically connected to the semiconductor device 1100. The electronic system 1000 may be a storage device including one or a plurality of semiconductor devices 1100, or an electronic device including a storage device. For example, the electronic system 1000 may be a solid state drive (SSD) device including at least one semiconductor device 1100, a universal serial bus (USB), a computing system, a medical device, or a communication device. However, embodiments of the present inventive concept are not limited thereto.

The semiconductor device 1100 may be a non-volatile memory device. For example, the semiconductor device 1100 may be a NAND flash memory device including the structure described above with reference to FIGS. 4 to 6 with respect to the semiconductor device 100. The semiconductor device 1100 may include a first structure 1100F, and a second structure 1100S on the first structure 1100F. In embodiments, the first structure 1100F may also be arranged next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a plurality of word lines WL, first and second gate upper lines UL1 and UL2, first and second gate lower lines LL1, LL2, and a plurality of memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT arranged between the lower transistors LT1 and LT2 and the upper transistors UT1 and UT2. The number of lower transistors LT1 and LT2 and the number of upper transistors UT1 and UT2 may be variously modified according to embodiments.

In embodiments, the upper transistors UT1 and UT2 may include a string selection transistor, and the lower transistors LT1 and LT2 may include a ground selection transistor. A plurality of gate lower lines (e.g., the first and second gate lower lines LL1 and LL2) may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2.

The common source line CSL, the plurality of gate lower lines (e.g., the first and second gate lower lines LL1 and LL2), the plurality of word lines WL, and a plurality of gate upper lines (e.g., the first and second gate upper lines UL1 and UL2) may be electrically connected to the decoder circuit 1110 through a plurality of first connection wires extending from the first structure 1100F to the second structure 1100S. A plurality of bit lines BL may be electrically connected to the page buffer 1120 through a plurality of second connection wires extending from the first structure 1100F to the second structure 1100S.

In the first structure 1100F, the decoder circuit 1110 and the page buffer 1120 may perform a control operation on at least one of the plurality of memory cell transistors MCT. The decoder circuit 1110 and the page buffer 1120 may be controlled by the logic circuit 1130.

The semiconductor device 1100 may communicate with the controller 1200 via an input/output (I/O) pad 1101 electrically connected to the logic circuit 1130. The I/O pad 1101 may be electrically connected to the logic circuit 1130 through an I/O connection wire extending from the first structure 1100F to the second structure 1100S.

The controller 1200 may include a processor 1210, a NAND controller 1220, and a host interface 1230. According to embodiments, the electronic system 1000 may include a plurality of semiconductor devices 1100, and here, the controller 1200 may control the plurality of semiconductor devices 1100.

The processor 1210 may control the overall operation of the electronic system 1000 including the controller 1200. The processor 1210 may operate according to certain firmware, and may access the semiconductor device 1100 by controlling the NAND controller 1220. The NAND controller 1220 may include a NAND interface 1221 that processes communication with the semiconductor device 1100. A control command for controlling the semiconductor device 1100, data to be recorded in the plurality of memory cell transistors MCT of the semiconductor device 1100, data to be read from the plurality of memory cell transistors MCT of the semiconductor device 1100, and the like may be transmitted via the NAND interface 1221. The host interface 1230 may provide a communication function between the electronic system 1000 and an external host. When receiving a control command from the external host via the host interface 1230, the processor 1210 may control the semiconductor device 1100 in response to the control command.

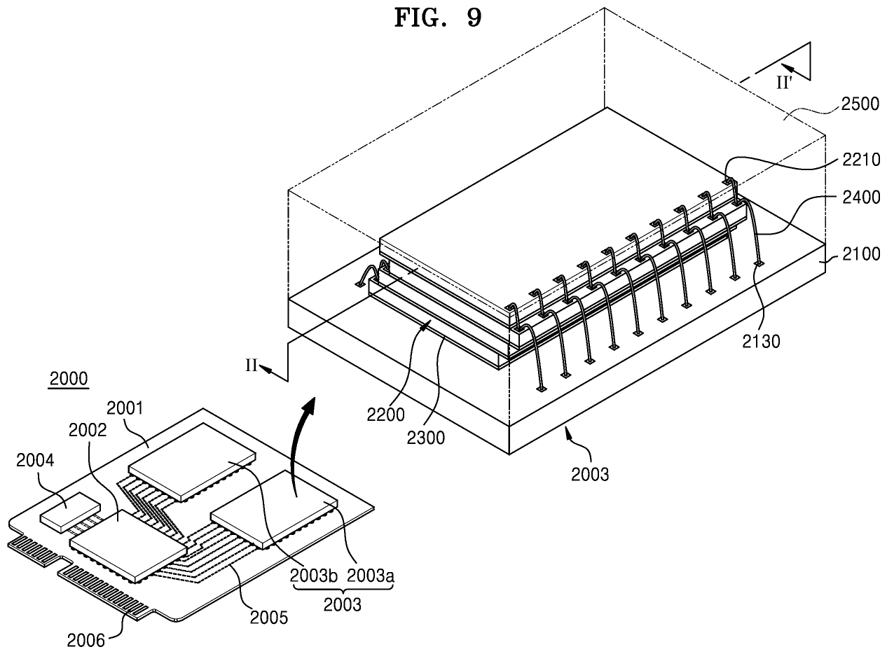

FIG. 9 is a perspective view schematically illustrating an electronic system 2000 including a semiconductor device, according to some embodiments of the present inventive concept.

Referring to FIG. 9, the electronic system 2000 according to some embodiments may include a main substrate 2001, a controller 2002 mounted on the main substrate 2001, one or more semiconductor packages 2003, and dynamic random access memory (DRAM) 2004. The semiconductor packages 2003 and the DRAM 2004 may be electrically connected to the controller 2002 via a plurality of wiring patterns 2005 formed on the main substrate 2001.

The main substrate 2001 may include a connector 2006 including a plurality of pins coupled to an external host. The number and arrangement of plurality of pins in the connector 2006 may vary according to a communication interface between electronic system 2000 and the external host. In embodiments, the electronic system 2000 may communicate with the external host according to an interface, such as a USB, peripheral component interconnect express (PCI-Express), serial advanced technology attachment (SATA), and M-Phy for a universal flash storage (UFS), but is not limited thereto. In embodiments, the electronic system 2000 may be operated by a power source supplied from the external host via the connector 2006. The electronic system 2000 may further include a power management integrated circuit (PMIC) that distributes the power source supplied from the external host to the controller 2002 and the semiconductor packages 2003.

The controller 2002 may record data in the semiconductor packages 2003 or may read data from the semiconductor packages 2003, and improve an operation speed of the electronic system 2000.

The DRAM 2004 may be a buffer memory for alleviating a speed difference between the semiconductor packages 2003, which are data storage spaces, and the external host. The DRAM 2004 included in the electronic system 2000 may also operate as a kind of cache memory, and may provide a space for temporarily storing data in a control operation for the semiconductor packages 2003. When the DRAM 2004 is included in the electronic system 2000, the controller 2002 may further include a DRAM controller for controlling the DRAM 2004, in addition to a NAND controller for controlling the semiconductor packages 2003.

The semiconductor packages 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the plurality of semiconductor chips 2200 on the package substrate 2100, an adhesive layer 2300 arranged on a lower surface of each of the plurality of semiconductor chips 2200, a connection structure 2400 for electrically connecting the plurality of semiconductor chips 2200 to the package substrate 2100, and a molding layer 2500 covering, on the package substrate 2100, the plurality of semiconductor chips 2200 and the connection structure 2400.

The package substrate 2100 may be a printed circuit board including a plurality of package upper pads 2130. Each of the plurality of semiconductor chips 2200 may include an I/O pad 2210. The I/O pad 2210 may correspond to the I/O pad 1101 of FIG. 8. Each of the plurality of semiconductor chips 2200 may include a plurality of gate stacks and a plurality of channel structures. Each of the plurality of semiconductor chips 2200 may include the structure described above with reference to FIGS. 4 to 6 with respect to the semiconductor device 100.

In embodiments, the connection structure 2400 may be a bonding wire for electrically connecting the I/O pad 2210 to the package upper pad 2130. Therefore, in the first and second semiconductor packages 2003a and 2003b, the plurality of semiconductor chips 2200 may be electrically connected to each other in a bonding wire method, and may be electrically connected to the package upper pad 2130 of the package substrate 2100. In embodiments, in the first and second semiconductor packages 2003a and 2003b, the plurality of semiconductor chips 2200 may also be electrically connected to each other by a connection structure including a through silicon via (TSV) instead of the bonding wire type of connection structure 2400.

In embodiments, the controller 2002 and the plurality of semiconductor chips 2200 may also be included in one package. In embodiments, the controller 2002 and the plurality of semiconductor chips 2200 may be mounted on a separate interposer substrate that is different from the main substrate 2001, and the controller 2002 and the plurality of semiconductor chips 2200 may be connected to each other by wires formed on the separate interposer substrate.

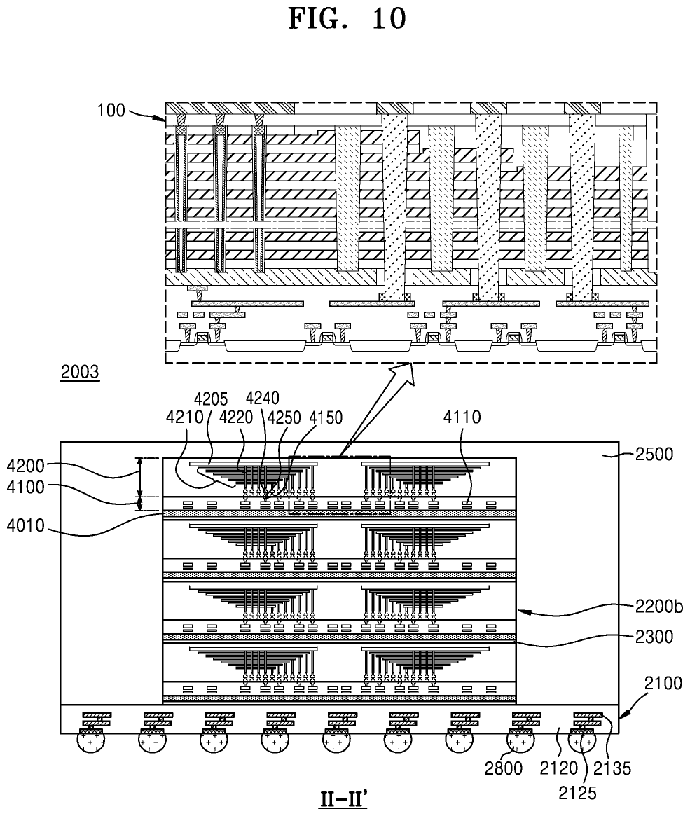

FIG. 10 is a cross-sectional view schematically illustrating semiconductor packages according to some embodiments of the present inventive concept. FIG. 10 illustrates, in more detail, components included in a cross-sectional view taken along line II-II′ of FIG. 9.

Referring to FIG. 10, in a semiconductor package 2003, each of semiconductor chips 2200b may include a semiconductor substrate 4010, a first structure 4100 on the semiconductor substrate 4010, and a second structure 4200 bonded to the first structure 4100 by a wafer bonding method on the first structure 4100.

The first structure 4100 may include a peripheral circuit region including a peripheral wire 4110 and first junction structures 4150. The second structure 4200 may include a common source line 4205, a gate stack structure 4210 between the common source line 4205 and the first structure 4100, memory channel structures 4220 passing through the gate stack structure 4210, and second junction structures 4250 electrically connected to the memory channel structures 4220 and the word lines WL of FIG. 8 of the gate stack structure 4210, respectively. For example, the second junction structures 4250 may be electrically connected to the memory channel structures 4220 and the word lines WL of FIG. 8 via bit lines 4240 electrically connected to the memory channel structures 4220 and gate connection wires electrically connected to the word lines WL of FIG. 8, respectively. The first junction structures 4150 of the first structure 4100 and the second junction structures 4250 of the second structure 4200 may be bonded while contacting each other. Bonded portions of the first junction structures 4150 and the second junction structures 4250 may include, for example, copper (Cu), but are not limited thereto.

Each of the semiconductor chips 2200b may further include the I/O pad 2210 of FIG. 9 electrically connected to peripheral wires 4110 of the first structure 4100.

The semiconductor chips 2200 of FIG. 9 and the semiconductor chips 2200b of FIG. 10 may be electrically connected to each other by the bonding wire type of connection structures 2400. However, in embodiments, semiconductor chips in one semiconductor package, such as the semiconductor chips 2200 of FIG. 9 and the semiconductor chips 2200b of FIG. 10, may be electrically connected to each other by a connection structure including a TSV.

The same reference numerals may refer to the same elements herein. Further, descriptions and details of well-known steps and elements may be omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits may not be described in detail so as not to unnecessarily obscure aspects of the present disclosure.

The terminology used herein is for the purpose of describing particular embodiments only and is not intended to limit the present disclosure. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify an entirety of list of elements and may not modify the individual elements of the list. When referring to “C to D”, this means C inclusive to D inclusive unless otherwise specified.

It will be understood that, although the terms “first”, “second”, “third”, and so on may be used herein to illustrate various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the scope of the present disclosure.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection. As used herein, “an element A connected to an element B” (or similar language) may mean that the element A is electrically connected to the element B and/or the element A contacts the element B. In addition, it will also be understood that when an element or layer is referred to as being “between” two elements or layers, it may be the only element or layer between the two elements or layers, or one or more intervening elements or layers may also be present.

In one example, when a certain embodiment may be implemented differently, a function or operation specified in a specific block may occur in a sequence different from that specified in a flowchart. For example, two consecutive blocks may actually be executed at the same time. Depending on a related function or operation, the blocks may be executed in a reverse sequence. Moreover, the function or operation in the specific block (e.g., step) may be separated into multiple blocks (e.g., steps) and/or may be at least partially integrated.

In descriptions of temporal relationships, for example, temporal precedent relationships between two events such as “after”, “subsequent to”, “before”, etc., another event may occur therebetween unless “directly after”, “directly subsequent” or “directly before” is not indicated.

The features of the various embodiments of the present disclosure may be partially or entirely combined with each other, and may be technically associated with each other or operate with each other. The embodiments may be implemented independently of each other and may be implemented together in an association relationship.

Spatially relative terms, such as “beneath,” “below,” “lower,” “under,” “above,” “upper,” and the like, may be used herein for ease of explanation to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

While the inventive concept has been particularly shown and described with reference to embodiments thereof, it will be understood that various changes in form and details may be made therein without departing from the spirit and scope of the following claims.

What is claimed is:

1. A semiconductor device comprising:
a substrate;
a stack structure on an upper surface of the substrate, wherein the stack structure includes gate electrodes and insulating layers alternately stacked in a vertical direction that is perpendicular to the upper surface of the substrate and has a stepped structure in a cross-sectional view;
a gate pad on the stack structure;
a first through via that extends through the stack structure in the vertical direction; and
a second through via that is spaced apart from the first through via in a horizontal direction that is parallel to the upper surface of the substrate,
wherein the second through via extends through the stack structure in the vertical direction,
wherein the second through via is electrically connected to a first gate electrode that is farthest one among the gate electrodes from the upper surface of the substrate in the vertical direction,
wherein the gate pad is on the first gate electrode and is in contact with the first gate electrode, and
wherein the first through via includes:
a vertical pattern;
a first protrusion that protrudes from the vertical pattern, wherein the first protrusion extends in the horizontal direction and overlaps at least a portion of the first gate electrode in the horizontal direction; and
a second protrusion that protrudes from the vertical pattern, wherein the second protrusion extends in the horizontal direction and overlaps a second gate electrode in the horizontal direction, wherein the second gate electrode is between the first gate electrode and the upper surface of the substrate and spaced apart from the second through via.

2. The semiconductor device of claim 1, wherein the first protrusion and the second protrusion have sidewalls recessed inward toward the vertical pattern.

3. The semiconductor device of claim 1, further comprising:
a first insulating pattern between the first protrusion and a sidewall of the first gate electrode that faces the first protrusion; and
a second insulating pattern between the second protrusion and a sidewall of the second gate electrode.

4. The semiconductor device of claim 3, wherein at least a portion of the first protrusion overlaps the first insulating pattern in the horizontal direction, and the second protrusion overlaps the second insulating pattern in the horizontal direction.

5. The semiconductor device of claim 3, wherein the first insulating pattern has a first thickness in the vertical direction, and the second insulating pattern has a second thickness in the vertical direction, and
wherein the second thickness is greater than the first thickness.

6. The semiconductor device of claim 1, wherein the gate pad includes a pad portion and a pad protrusion,
wherein the pad portion extends in the horizontal direction, and
wherein the pad protrusion protrudes from the pad portion and extends in the vertical direction.

7. The semiconductor device of claim 6, wherein the pad protrusion extends around a sidewall of the second through via.

8. The semiconductor device of claim 1, further comprising:
a first sidewall insulating pattern on an upper surface of the gate pad, wherein the first sidewall insulating pattern extends around a sidewall of the second through via;
a second sidewall insulating pattern between the second through via and the insulating layers that faces the second through via, wherein the second sidewall insulating pattern extends around the sidewall of the second through via;
a third insulating pattern on the first gate electrode, wherein the third insulating pattern extends around the sidewall of the second through via; and
a fourth insulating pattern on the second gate electrode, wherein the fourth insulating pattern extends around the sidewall of the second through via.

9. The semiconductor device of claim 8, wherein the second sidewall insulating pattern is connected to the third insulating pattern and the fourth insulating pattern.

10. The semiconductor device of claim 1, wherein, from a plan view, the first through via and the second through via are alternately arranged in the horizontal direction.

11. The semiconductor device of claim 1, further comprising:
a circuit transistor on the substrate;
a wiring structure on the substrate, wherein the wiring structure is electrically connected to the circuit transistor;
an interlayer insulating layer on the substrate, wherein the interlayer insulating layer is on the circuit transistor and the wiring structure; and
a common source plate on the interlayer insulating layer, wherein the gate electrodes are on the common source plate, and the second through via passes through the common source plate to be electrically connected to the wiring structure.

12. A semiconductor device comprising:
a substrate;
a stack structure on an upper surface of the substrate, wherein the stack structure includes gate electrodes and insulating layers alternately stacked in a vertical direction that is perpendicular to the upper surface of the substrate and has a stepped structure in a cross-sectional view;
a gate pad on the stack structure;
a first through via that extends through the stack structure in the vertical direction, wherein the first through via includes a first insulating material;
a second through via that is spaced apart from the first through via in a horizontal direction that is parallel to the upper surface of the substrate, wherein the second through via extends through the stack structure in the vertical direction and the second through via is electrically connected to a first gate electrode that is farthest one among the gate electrodes from the upper surface of the substrate in the vertical direction; and
a vertical structure that is spaced apart from the first through via and the second through via, wherein the vertical structure extends through the stack structure in the vertical direction and includes a second insulating material,
wherein the gate pad is on the first gate electrode and is in contact with the first gate electrode, and
wherein the first through via includes:
a vertical pattern;
a first protrusion that protrudes from the vertical pattern, wherein the first protrusion extends in the horizontal direction and overlaps at least a portion of the first gate electrode in the horizontal direction; and
a second protrusion that protrudes from the vertical pattern, wherein the second protrusion extends in the horizontal direction and overlaps a second gate electrode in the horizontal direction, wherein the second gate electrode is between the first gate electrode and the upper surface of the substrate and spaced apart from the second through via.

13. The semiconductor device of claim 12, wherein the first protrusion and the second protrusion have sidewalls recessed inward toward the vertical pattern.

14. The semiconductor device of claim 12, further comprising:
a first insulating pattern between the first protrusion and a sidewall of the first gate electrode that faces the first protrusion; and
a second insulating pattern between the second protrusion and a sidewall of the second gate electrode.

15. The semiconductor device of claim 12, wherein a lower surface of the first through via and a lower surface of the vertical structure are located at an equal vertical distance from the upper surface of the substrate.

16. The semiconductor device of claim 12, further comprising:
a first sidewall insulating pattern on an upper surface of the gate pad, wherein the first sidewall insulating pattern extends around a sidewall of the vertical structure;
a second sidewall insulating pattern between the vertical structure and the insulating layers that faces the vertical structure, wherein the second sidewall insulating pattern extends around the sidewall of the vertical structure;
a third insulating pattern on the first gate electrode, wherein the third insulating pattern extends around the sidewall of the vertical structure; and
a fourth insulating pattern on the second gate electrode, wherein the fourth insulating pattern extends around the sidewall of the vertical structure.

17. The semiconductor device of claim 16, wherein the second sidewall insulating pattern is connected to the third insulating pattern and the fourth insulating pattern.

18. An electronic system comprising:
a first substrate;
a semiconductor device on the first substrate; and
a controller electrically connected to the semiconductor device on the first substrate, wherein the semiconductor device includes:
a second substrate;
a stack structure disposed on an upper surface of the second substrate, wherein the stack structure includes gate electrodes and insulating layers alternately stacked in a vertical direction that is perpendicular to the upper surface of the second substrate and has a stepped structure in a cross-sectional view;
a gate pad on the stack structure;
a first through via that extends through the stack structure in the vertical direction; and
a second through via that is spaced apart from the first through via in a horizontal direction that is parallel to the upper surface of the second substrate,
wherein the second through via extends through the stack structure in the vertical direction,
wherein the second through via is electrically connected to a first gate electrode that is farthest one among the gate electrodes from the upper surface of the second substrate in the vertical direction,
wherein the gate pad is on the first gate electrode and is in contact with the first gate electrode, and
wherein the first through via includes:
a vertical pattern;
a first protrusion that protrudes from the vertical pattern, wherein the first protrusion extends in the horizontal direction and overlaps at least a portion of the first gate electrode in the horizontal direction; and
a second protrusion that protrudes from the vertical pattern, wherein the second protrusion extends in the horizontal direction and overlaps a second gate electrode in the horizontal direction, wherein the second gate electrode is between the first gate electrode and the upper surface of the second substrate and spaced apart from the second through via.

19. The electronic system of claim 18, wherein the first protrusion and the second protrusion have sidewalls recessed inward toward the vertical pattern.

20. The electronic system of claim 18, further comprising:
a first insulating pattern between the first protrusion and a sidewall of the first gate electrode that faces the first protrusion; and
a second insulating pattern between the second protrusion and a sidewall of the second gate electrode,
wherein the first insulating pattern has a first thickness in the vertical direction, and the second insulating pattern has a second thickness in the vertical direction, and
wherein the second thickness is greater than the first thickness.
